(19) United States
(12) Patent Application Publication
(10) Pub. No.: US 2026/0028223 A1
(43) Pub. Date: Jan. 29, 2026

(54) HIGH SPEED MANUFACTURE OF MICRO-ELECTRICAL MECHANICAL SYSTEMS ARRAYS

(71) Applicant: THE UNIVERSITY OF BRITISH COLUMBIA, Vancouver (CA)

(72) Inventors: Jonas Welsch, Vancouver (CA); Edmond Cretu, Vancouver (CA); Robert Rohling, Vancouver (CA)

(21) Appl. No.: 18/993,452

(22) PCT Filed: Jul. 13, 2023
(86) PCT No.: PCT/CA2023/050948

§ 371 Date: Jan. 10, 2025

Related U.S. Application Data
(60) Provisional application No. 63/388,923, filed on Jul. 13, 2022.

(51) Int. Cl. B81C 1/00; B81B 3/00; B81C 99/00

(52) U.S. Cl. CPC B81C 1/00214; B81C 99/001; B81B 3/0021; B81B 2201/0264; B81C 2201/0111; B81C 2201/0146; B81C 2201/019; B81C 2900/00

(57) ABSTRACT

Methods, systems, and techniques for the high speed manufacture of micro-electrical mechanical systems (MEMS) arrays, such as arrays of polymeric capacitive micromachined ultrasonic transducers (CMUTs). A sheet of material from which to form cavities for the devices is obtained, and physical or energy projections are projected into the material to form the cavities. Upper and lower surfaces of the material are respectively contacted with and bonded to upper and lower metalized films. The metalized portions of the upper and lower metalized films may serve as electrodes for a CMUT, and the films themselves may be the CMUT's substrate and membrane.

### TECHNICAL FIELD

The present disclosure generally relates to large-scale fabrication of micro-electrical mechanical systems (MEMS) devices and arrays, and more particularly large, flexible arrays of capacitive micromachined ultrasonic transducers (CMUTs).

### BACKGROUND

Ultrasound imaging is the most widely used medical imaging modality in the world in terms of images created annually. In ultrasound imaging, ultrasonic waves emitted by a transducer travel through a material and reflect off of interfaces to other materials with different acoustic impedances. The reflected echoes travel back to a transducer where they are processed to form an ultrasound image. Ultrasound transducers transform electrical energy into acoustic energy, and vice versa.

CMUTs are an alternative technology to piezoelectric-based transducers. A CMUT is essentially a parallel-plate capacitor with an electrode at its bottom fixed to a substrate, with a membrane suspended over a cavity and sealed along its edges. A metallic electrode is patterned on top of the suspended membrane. When electrical signals are applied across the electrodes, the resulting mechanical motion of the membrane produces acoustic waves in the medium in contact with the membrane; this represents an electrical to acoustic energy transfer. Polymeric CMUTs (poly-CMUTs) are in effect CMUTs where the vibrating membrane is made of a polymer material. The resonant frequency and acoustic power depend on their diameter and thickness. Fabrication of poly-CMUTs is typically done in a cleanroom using photolithography to pattern and build the layers of the device. U.S. Pat. Nos. 10,509,013, 10,564,132, and 10,598,632 by Gerardo, Rohling and Cretu, the entireties of all of which are hereby incorporated by reference herein, disclose methods of microfabrication of ultrasonic transducers using polymer membranes, resulting in reductions of poly-CMUT required operating voltages.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to a first aspect, there is provided a method of fabricating MEMS arrays, the method comprising: providing a sheet of thin film material; contacting said material with a die comprising projections, the projections capable of puncturing said material to form shaped cavities in a pattern; contacting said material with an upper and a lower metalized film; and laminating said films by the addition of energy.

The method may be performed without chemical waste.

The energy may come from heat and/or pressure.

The composition of said material may be polymeric, metallic, or include a polyimide.

The MEMS devices may be poly-CMUTs and/or CMUTs, or other devices with a similar suspended membrane structure (e.g., pressure sensors).

According to additional aspects, there are provided MEMS devices as made by the foregoing method; CMUTs as made by the foregoing method; poly-CMUTs as made by the foregoing method, without a sandwiched electrode and fabricated through fully mechanical means; and a method for shaping MEMS devices according to the foregoing method.

According to another aspect, there is provided a method of fabricating an array of micro-electrical mechanical systems devices, the method comprising: obtaining a sheet of material from which to form cavities for the devices; projecting physical or energy projections into the material to form the cavities in the material; respectively contacting upper and lower surfaces of the material with the cavities with upper and lower metalized films; and respectively bonding the upper and lower surfaces of the material with the upper and lower metalized films.

The physical projections may be projected into the material to form the cavities.

The physical projections may comprise a punching stamp.

The physical projections may comprise a stamp die.

The physical projections may comprise a rotating cylinder die.

The energy projections may be projected into the material to form the cavities.

The energy projections may comprise lasers.

The energy projections may comprise electrical discharges.

The physical projections may comprise steam jets.

The material may be polymeric.

The material may comprise polyimide.

The material may comprise polyethylene terephthalate.

The material may be biaxially oriented polyethylene terephthalate and be between 600 nm to 1.5 μm thick.

The material may be metallic.

The MEMS devices may be capacitive micromachined ultrasonic transducers, such as polymeric capacitive micromachined ultrasonic transducers.

The upper and lower surfaces of the material with the cavities may be contacted with the upper and lower metalized films such that metalized portions of the upper and lower metalized films are respectively situated in the cavities.

The bonding may comprise laminating.

The laminating may be performed using a roll laminator at a temperature of at least 230° C.

The laminating may be performed at a pressure of at least 1 bar.

The laminating may be performed at a pressure of approximately 3 bar and at a temperature of approximately 243° C.

The bonding may comprise gluing.

The lower metalized film may comprise a flexible substrate of the devices.

The metalized films may respectively comprise lattice patterns, and the cavities may be located at locations at which the lattice patterns overlap.

According to another aspect, there is provided an apparatus for fabricating an array of micro-electrical mechanical systems devices, the apparatus comprising: a pair of stamping rollers, wherein the pair of stamping rollers comprises a cylinder die and is configured to receive and stamp cavities into spacer film using the cylinder die; at least one pair of film rollers, wherein the at least one pair of film rollers is configured to receive the stamped spacer film and metalized films and to compress the stamped spacer film between the metalized films; and a pair of laminating rollers configured to receive and laminate the compressed spacer and metalized films.

The at least one pair of film rollers may comprise a first pair of film rollers and a second pair of film rollers, wherein: the first pair of film rollers is configured to receive and compress the stamped spacer film and a first one of the metalized films; and the second pair of film rollers is configured to receive the spacer film and the first one of the metalized films after passing through the first pair of film rollers and a second one of the metalized films, and to compress the stamped spacer film between the metalized films, wherein the first one of the metalized films is thicker than the second one of the metalized films.

The apparatus may further comprise: a stamping aid roller pair configured to receive and compress the spacer film and a stamping aid, wherein the compressed spacer film and stamping aid are fed into the pair of stamping rollers and into the first pair of film rollers; and a hard edge positioned to peel the stamping aid away from spacer film after exiting the first pair of film rollers.

This summary does not necessarily describe the entire scope of all aspects. Other aspects, features and advantages will be apparent to those of ordinary skill in the art upon review of the following description of specific embodiments.

### BRIEF DESCRIPTION OF THE DRAWINGS

Further features and advantages of the present disclosure will become apparent from the following detailed description, taken in combination with the appended drawings, in which:

FIG. 1 is a shaded cross-sectional drawing illustrating a single poly-CMUT element in a cross-section showing the component layers of membrane, electrodes, polymeric layer, insulation, and substrate;

FIG. 2A is a shaded drawing of another embodiment of a poly-CMUT with fewer layers than the poly-CMUT of FIG. 1, and which is a layup of the device illustrated in FIG. 2B, according to an example embodiment;

FIG. 2B depicts a layup of a four cavity device and electrodes after alignment to a metalized polyamide film and lamination together at 235° C., and application of pressure in a roll laminator, according to an example embodiment;

FIG. 3 is a photographic reproduction of two views of an example mask used for stamping and metal evaporation, according to an example embodiment;

FIG. 4A is a graphical representation of the magnitude of displacement of a poly-CMUT membrane under 120 V DC and 60 V AC measured in a Laser Doppler Vibrometer (LDV), and FIG. 4B is a photographic reproduction of the corresponding poly-CMUT cell under 10× magnification in which both electrodes and the larger outline of the cavity are visible, according to an example embodiment;

FIG. 5A is an illustration of one pattern of shaped poly-CMUT cavities according to an example embodiment;

FIGS. 5B to 5D are pictures of example first and second sheets of MEMS devices manufactured in a roll-to-roll setting, according to example embodiments;

FIG. 6 depicts a roller pair comprising a die for stamping a spacer film for preparing an array of shaped poly-CMUT cavities, according to an example embodiment; and

FIG. 7 depicts a roll-to-roll manufacturing apparatus for preparing an array of shaped poly-CMUT cavities, according to an example embodiment.

### DETAILED DESCRIPTION

The manufacture of arrays of CMUTs using conventional methods is painstaking. One current limitation in the state of the art is the limit on the maximum speed of CMUT production. Another limitation is the need for multiple fabrication steps on multiple pieces of fabrication equipment with manual transport of materials between those different pieces of equipment. Such equipment includes wet benches, mask aligners, ion etchers, driers, furnaces, and evaporators. Another limitation of CMUT manufacture is the maximum size of the CMUT transducer array that can be made using conventional fabrication techniques, which is typically a few centimeters in diameter and insufficient for applications that require meters-long arrays. Another limitation in the traditional manufacture methods are the type and number of liquid and gas chemicals needed such as photoresists, acids, bases, and developers, many of which are toxic and difficult to dispose of. A method to manufacture CMUTs that overcomes one or more of these limitations is therefore desirable.

The present disclosure is directed at new methods, systems, and techniques for fabricating CMUTs and other MEMS devices that utilise cavities in a layer to accommodate electromechanical coupling. While CMUTs are the focus of the example embodiments below, the present disclosure contemplates other types of MEMS devices with those types of cavities, such as accelerometers, pressure sensors, speakers, and gyroscopes as well. In at least some embodiments. the cavities are created by mechanically stamping ultra-thin films and laminating them in between previously metalized films. The benefits are, ideally, the avoidance of any wet chemical processing and the elimination of the maximum size restriction described above in respect of the traditional microfabrication method and equipment. At least some embodiments also allow a variable compromise to be made where the precision of the stamped structures is inversely proportional to the speed and scale of fabrication.

In at least some embodiments, multiple technical problems had to be overcome to accomplish this. For example, the cavities used are small (on the order of millimetres or smaller) and the stamping dies are fabricated to stamp those cavities. This means tools and accuracy of tool manufacturing are to be in the region of sub 1/100^{th} of a millimetre.

Another factor is the quality and thickness of the spacer film. For example, as mentioned above it is very thin while still being structurally stable enough to be handled during fabrication steps. If the film is damaged or the cutting edge of the die has a defect the film will rip and manufacturing will fail.

In the present disclosure, the following terms have the following meanings:
(a) A “polymer-based capacitive micromachined ultrasonic transducer” or “poly-CMUT” is a layered ultrasonic device with a polymeric membrane containing an embedded upper electrode suspended above a cavity. Examples of a poly-CMUT are found, for example, in U.S. Pat. No. 10,598,632 by Gerardo, Rohling and Cretu. In contrast to conventional, non-polymer-based CMUTs, in a poly-CMUT the top electrode may be embedded within two polymer layers, with the bottom layer being thinner than the top layer. Combined with forming a sufficiently thin CMUT cavity, this structure permits the CMUT to reach the MHz operative region without requiring unacceptably high operating voltages. Poly-CMUT elements may be formed by the methods disclosed in U.S. Pat. Nos. 10,598,632 by Cretu et al., for example.
(b) “Micro-electrical mechanical systems” or “MEMS” are miniature electro-mechanical devices, such as poly-CMUTs. In at least some embodiments, these comprise microsensors and microactuators. Piezoelectric materials may be used to shape the resonant frequency of MEMS devices, which may affect the performance of those devices. For example, piezoelectric materials may affects the performance of MEMS devices such as accelerometers, energy harvesters, or strain gauges.
(c) The term “spacer film” means the sheet of material from which shaped cavities are formed for the CMUT or MEMS array, and which is stamped/perforated, by hand and/or in an automated system. Used in the manufacture of the poly-CMUTs are polyimide (e.g., Kapton™), polyethylene terephthalate (PET), of which an example is Mylar™, and gold for the electrode. Other spacer films may comprise, for example, paper, Chitosan, polystyrene (PS) or other materials suitable for use as thin films that are suitable for bonding, such as through lamination, to the substrate and membrane layers of the MEMS device.
(d) The term “stamping” as used herein means the removal of portions of spacer film by pressing a die comprising projections into that spacer film.
(e) “Low power” or “passive power” means wireless power transfer using electromagnetic fields, usually performed at a frequency that matches the resonant frequency of the poly-CMUT elements.
(f) An “array” means a group of poly-CMUT elements aligned side by side in a one-dimensional (1-D) arrangement, multiple linear arrays located side by side (1.5-D) or a two-dimensional array (2-D array, also referred to as a “matrix array”) of poly-CMUT elements in communication with each other and capable of communication (once connected or active) with user interfaces either by wired communication or wireless signals.
(g) The term “shaped cavities” are perforations impressed or otherwise formed in spacer film (e.g., using a laser) during poly-CMUT manufacture. They may be shaped circularly, as polygons, or other closed contour shapes, for example, to accommodate the desired CMUT or MEMS perimeter.
(h) A “die comprising projections” is a solid material with hard projections capable of perforating spacer film. Examples of a die comprising projections are rotating cylinder dies in a roll-to-roll set up, punching stamps, and manual or automated leather stamp die. The projections may be metal, mineral or a polymer, or combination of two or three of these elements. In other embodiments, one or more lasers may be used to perforate spacer film. Whatever is used to perforate spacer film, the result is that shaped cavities are formed in the spacer film. In still other embodiments, a means for evaporation or steam jets may be used to form shaped cavities in spacer film. For example, in at least some embodiments, holes may be created in spacer film via evaporation through electrical discharges or lasers (i.e., through thermal evaporation of sections). More generally, a “die comprising perforation means” comprises a solid material with means for selectively perforating spacer film, with those means comprising, in various embodiments, projections, lasers, means for evaporation, steam jets, or the like.
(i) “Photoacoustic imaging” or “PA imaging” is a biomedical imaging modality in which nonionizing laser pulses are delivered into biological tissues. Some of the delivered energy will be absorbed and converted into heat, leading to transient thermoelastic expansion and thus wideband (i.e., MHZ) ultrasonic emission. Typical reception frequency responses of classical piezoelectric (PZT) ultrasonic imaging transducers, based on PZT technology, are not sufficiently broadband to fully preserve the entire information contained in photoacoustic signals. CMUTs exhibit both higher sensitivity and significantly broader frequency response in reception, making them more effective in association with PA imaging applications than PZT ultrasound.

### Power

Electrical charges trapped in a poly-CMUT's membrane act as a built-in DC bias. Poly-CMUTs can in at least some embodiments accordingly be used as a passive device (i.e., no external power is applied to the poly-CMUT) during reception of an acoustic signal and conversion of that acoustic signal into an electrical signal. Alternatively, excitation voltages of various amplitudes may be applied to the poly-CMUT. For example, in some embodiments a relatively low excitation voltage may suffice (e.g., 10 V_{DC}+12 V_{AC}); in some other embodiments, higher voltages may be required, such as when a relatively thick spacer film 130 is used that results in a relatively thick cavity 170.

Wireless communication also includes wireless power transfer in some embodiments, wherein a transmitter device driven by electric power from a power source generates a time-variant electromagnetic field that transmits power across a space to a receiver device, which extracts power from the field and provides it to an electrical load. Examples of wireless power transfer include inductive coupling, resonant inductive coupling, capacitive coupling, magnetodynamic coupling, acoustic coupling, and power transmission using microwaves and light waves. The coupling can be nearfield coupling or intermediate coupling. In the context of electromagnetic energy, the energy that is transferred can be electromagnetic waves with frequencies in the KHz to MHz range, microwaves, x-rays, and light waves such as solar energy and lasers. Such waves can be produced using an antenna or other coupling devices. For example, the waves may comprise electromagnetic energy generated to perform simultaneous magnetic resonance imaging or x-ray imaging. Other types of energy that may be transferred comprise kinetic energy from acoustic waves and surface waves, and thermal energy from heat. The coupler can be attached externally to the poly-CMUT elements or embedded directly in the poly-CMUT elements. The advantage of using wireless power transfer is to increase convenience and safety, and reduce the size, weight, cost, and complexity of the poly-CMUT elements; this may be particularly beneficial when the poly-CMUT elements comprise part of a wearable patch. For example, a lightweight patch may be unobtrusive to the wearer, and a patch may be implanted or embedded in a patient in which wires are prohibited because of concerns about infection.

Poly-CMUTs can be manufactured on flexible substrates for wearable applications. This can be difficult with silicon-based CMUTs since they need rigid substrates, and manufacturing a flexible substrate is impossible when the substrate is manufactured using ceramic piezoelectric materials.

Previous research is either focused on roll-to-roll MEMS processes using photolithography or solid-state device fabrication like U.S. Pat. No. 8,779,650. These references focus on the use of wet or dry etching processes and UV sensitive chemicals by selectively hardening previously deposited soft layers. In contrast, the methods, systems, and techniques described herein may be entirely mechanical and not involve any etching or curing to form the functional shape of the CMUT.

### Manufacture of the Poly-CMUT Component Array

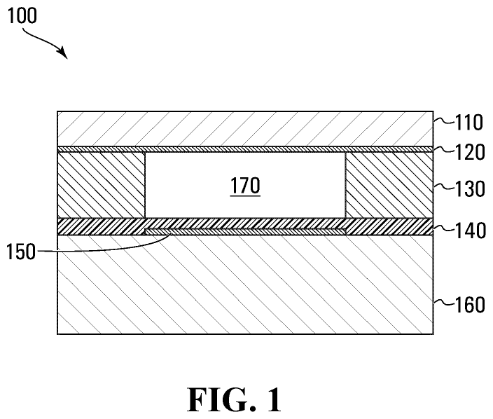

FIG. 1 depicts a MEMS device comprising an example poly-CMUT 100. The poly-CMUT comprises four main components: a substrate 160; a spacer film 130 that, in FIG. 1, comprises PET; top and bottom electrodes 120 and 150, which in FIG. 1 each is made of aluminum; and a membrane 110. FIG. 1 also depicts a cavity 170 in the poly-CMUT 100; while depicted as part of the poly-CMUT 100 in FIG. 1. In FIG. 1. the spacer film 130 is sandwiched between the top electrode 120 and a bottom layer of acrylate insulation 140, with a bottom aluminum electrode 150 located between a bottom side of the acrylate insulation 140 and above the substrate 160. For instance, the substrate 160 may be a 100 um polyimide film. Indeed, the substrate 160 may be any flexible film, such as aluminum foil, paper, or other polymers. Any flexible film may be used as the substrate 160, although in at least some embodiments the substrate 160 has the same or larger thickness as the membrane 110 or mechanically stronger than the membrane 110. The substrate 160 can also adhere to the spacer film 130 or, if another layer such as the acrylate insulation 140 is present, to that other layer. Adherence of the flexible film to the spacer film 130 may be obtained through lamination, gluing, or another suitable method. To create a functioning device, the substrate 160 can either be conductive itself or coated with a conductive material. To reduce parasitic capacitances and resistances the conductive layer can be patterned through, for example, a process like sputtering on an oil mask. If needed, the conductive layer can be insulated by acrylate, a process Steiner GmbH offers for capacitor foils for example, or by one or more other suitable insulators such as silicon dioxide.

In FIG. 1, first the bottom film in the form of the substrate 160 and top film in the form of the membrane 110 may be metalized in the pattern needed for resulting devices, example applications of which are described below. This may be done by screen printing a mineral oil mask and sputtering the selected electrode material, thereby patterning it. After this, spacer film in the form of ultrathin polymer or metal films are stamped to create the shaped cavities used by the electrodes 120 and 140, which effectively function as plates of a capacitor, to move or vibrate. Each of the shaped cavities can be as small as 200 μm across with a distance of less than 1 mm from each other. The film is then aligned to the substrate 160 and top film and laminated together, either just through heat and pressure or with an ultrathin layer of polymer glue.

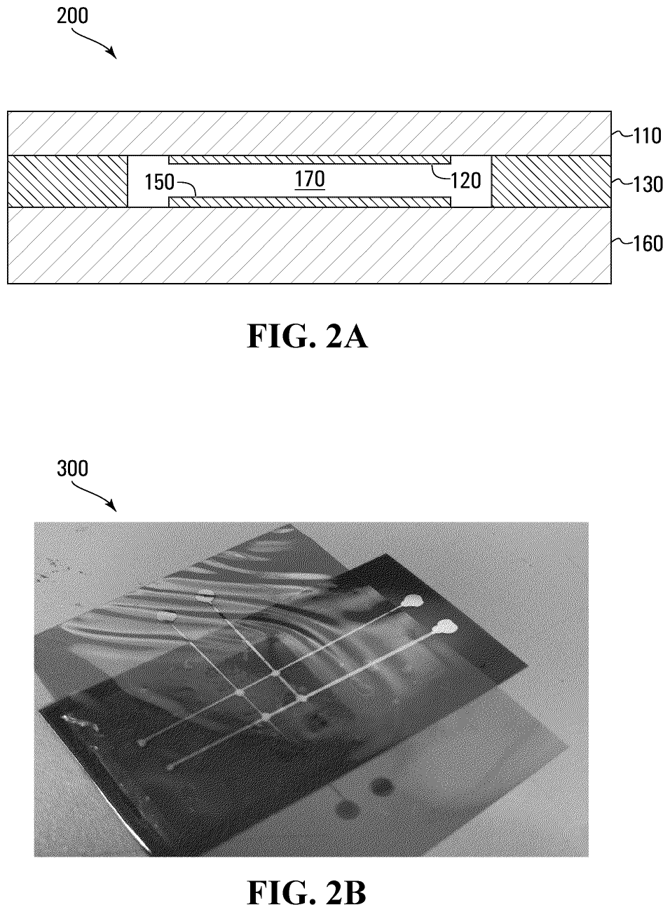

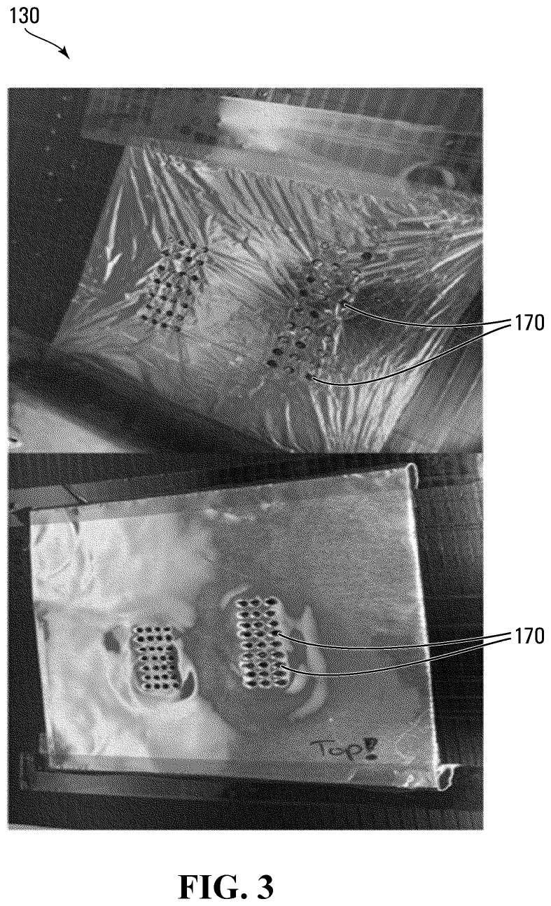

The entire process can either be done by vertical stamping in steps or combined in a roll-to-roll stamping and lamination machine. The properties of the resulting devices are managed through the film thickness and width of the cavity 170. For example, to keep operating voltages at a practical level, the spacer film 130 is preferably as thin as possible. In at least some embodiments of the poly-CMUT 100, for example, the distance between the two electrodes 120, 150 does not surpass 1 μm so as to cause the poly-CMUT's 100 operating voltage to be below 230 Volts. The spacer film 130 also adheres to the substrate 160 and membrane 110 layers. In FIG. 1, the spacer film 130 indirectly adheres to the substrate 160 via the insulation layer 140; however, as shown in respect of FIG. 2 and as discussed below, the spacer film 130 may also be directly bonded to the substrate 160. If glue layers are used, it is preferable for them to be extremely thin. In one example, heat and pressure may be used to laminate ultra-thin PET acting as the spacer film 130 to the polyamide films acting as the substrate 160 and membrane 110.

In order to create a functioning MEMS device, it is preferable for the device to have space to move. In the case of the poly-CMUT 100, the membrane 110 is suspended over the cavity 170. For most MEMS devices this cavity 170 also dictates the properties of the device, like resonant frequencies or sensitivity. In respect of FIG. 1, the shaped cavities are stamped from the spacer film 130. This can be done entirely by hand, through a vertical stamping machine, or in a roll-to-roll setting for larger areas. To form the shaped cavities, the spacer film may be perforated by a die comprising projections, such as by being stamped by the stamping section of a roll-to-roll lamination machine to create arrays comprising multiple shaped cavities for multiple MEMS devices at once.

After creating the shaped cavities, the three films in the form of the membrane 110, spacer film 130, and substrate 160 are aligned with each other and stacked so that the conductive layers in the form of the electrodes 120 and 150 are placed as shown in FIG. 1. In at least some embodiments they were then heated and pressed through two rolls at a pressure of around 3 bar and at a temperature of 243° C. This laminated the films while still ensuring the membrane 110 was suspended over the cavity 170. In at least some embodiments in which this process was done in a roll-to-roll setting, the final devices are cut from a continuous film.

Lamination temperature and pressure are inversely related to each other (i.e., increased pressure reduces the required temperature). Generally speaking, lamination may be performed at a pressure of 1 bar and a temperature of 243° C. to a pressure of 5 bar and a temperature of 210° C., with temperature decreasing as pressure increases. Pressure should remain low enough so as not to compress the spacer film 130 such that the cavities 170 close.

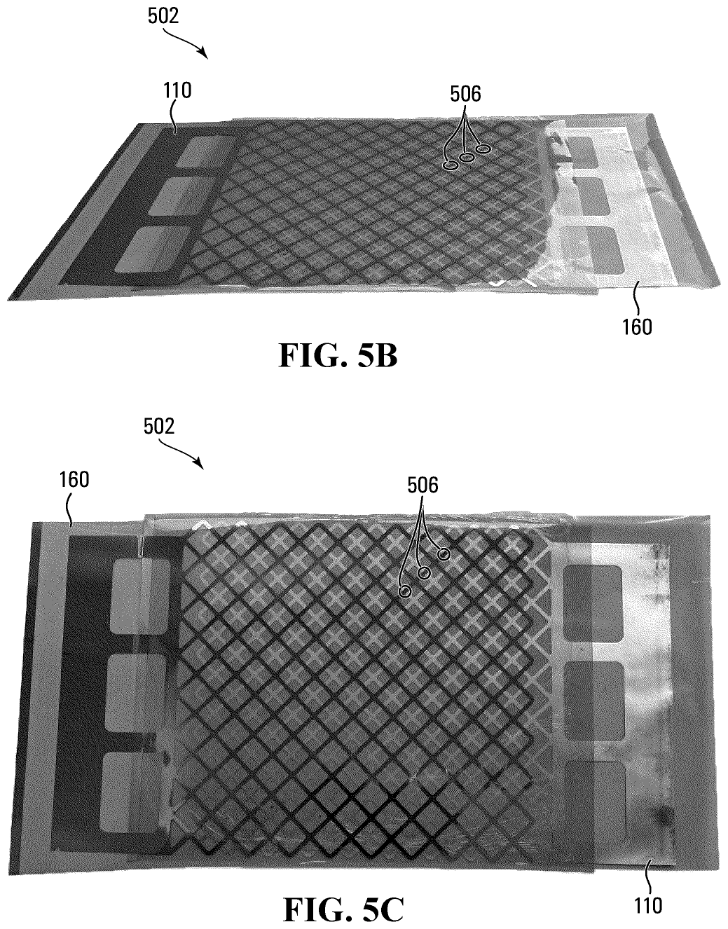

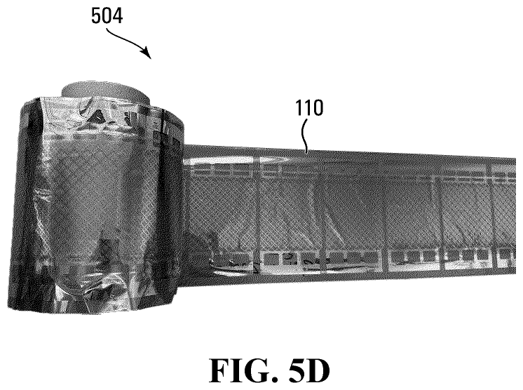

FIG. 5A illustrates an example of a metal lattice pattern 500 that can be formed on, for example, the substrate 160 or membrane 110.

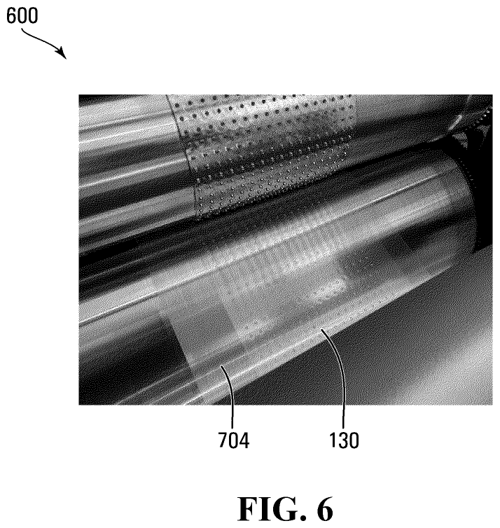

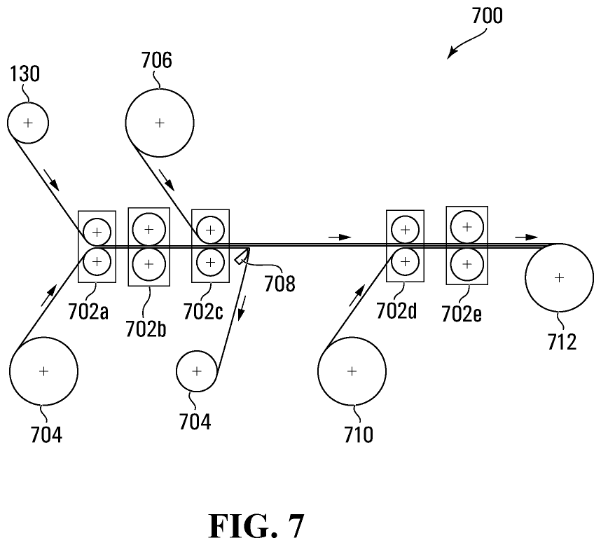

A stamped spacer film 130 with a cavity diameter of 0.8 mm and a distance between the cavities 170 of 5 mm and the stamping die used in a roll-to-roll machine is illustrated in the photographic reproduction 600 of FIG. 6. The stamping die of FIG. 6 comprises a rotating cylinder die, and may be used in the system described in respect of FIG. 7 below.

FIGS. 5B to 5D depicts pictures of example first and second sheets 502 and 504 of MEMS devices manufactured in a roll-to-roll setting, as described above, comprising a pair of the metal lattice patterns 500. FIG. 5B depicts a front perspective view of the first sheet 502; FIG. 5C depicts a top plan view of the first sheet 502; and FIG. 5D depicts a top side of a second sheet 504. The first sheet 502 of MEMS devices may be cut from the second sheet 504.

As evidenced particularly in FIGS. 5B and 5C respectively showing top and bottom plan views of the first sheet 502 of devices, the fabricated devices comprise the membrane 110, which has been metalized to form the top electrodes 120 and bondpads electrically coupled to the top electrodes 120; and a flexible substrate 160, which has been metalized to form the bottom electrodes 150 and bondpads electrically to the bottom electrodes 150. The cavities 170 for the devices are located at the intersections 506 of the top and bottom electrodes 120 and 150 (i.e., where the electrodes 120 and 150 overlap) and are accordingly not visible in FIGS. 5B and 5C.

Further expansion of the size of manufactured arrays is possible by assembly using overlapping tape/patches. This is a method of modular assembly for arrays of poly-CMUT cells disposed in regular patterns (one by two, two by four. four by four, and so on) on a flexible substrate 160. In this method, a flexible tape or patch serves as mechanical substrate 160 for the fabrication of the array of the transducers on its top surface, while the bottom side may be specially treated in order to be adhesive. To ensure electrical interconnectivity between rows of cells fabricated on the top surface, each row has associated bondpads (electrical interconnect surfaces) at both margins of the patch/tape. A via mechanism, similar to the one used in fabricating flexible PCBs, connects the margin bondpads on the top surface electrically to margin bondpads patterned on the bottom surface of the tape/patch. The top and bottom sets of margin bondpads are aligned.

When the tape being made for wrapping a cylindrical surface such as a pipe of a defined circumference, the distance between consecutive rows of transducer cells (disposed in a direction transverse to the margin of the tape [i.e., consecutive rows extend axially along the cylindrical surface]) is preferably made such that the diameter of the cylinder corresponds to an integer number of rows disposed around its circumference. The next tape wind will then align the next set of transducer rows with the previous ones and provide electrical interconnectivity by overlapping the top margin bondpads of the previous tape with the bottom margin bondpads of the next wind of tape.

In at least some embodiments, to ensure a better self-alignment, the tape structure has relief alignment lock-in patterns, such as trenches and wedges, for example, to enforce and stabilize the alignment of the connections among transducers.

In other embodiments, the alignment of bondpads described above is also used in flexible patches of various shapes and sizes, bands, foils, fabrics, and formed shapes of the poly-CMUT arrays.

FIG. 7 depicts an example system 700 that may be used to manufacture MEMS devices using a roll-to-roll laminator, according to an example embodiment. The system comprises various pairs of rollers: a stamping aid roller pair 702a, a pair of stamping rollers 702b, a first pair of film rollers 702c, a second pair of film rollers 702d, and a pair of laminating rollers 702e. The pair of laminating rollers 702e comprise part of a roll-to-roll laminator.

The spacer film 130, which in FIG. 7 is a PET such as Mylar™, is pulled into the stamping aid roller pair 702a together with a stamping aid 704. The stamping aid 704 may be a relatively thick layer of PET, for example, to which stamped out portions of the spacer film 130 adhere following stamping. The spacer film 130 is pulled into the first roller pair 702a and compressed together with the stamping aid 704. The compressed spacer film 130 and stamping aid 704 are pulled into the pair of stamping rollers 702b, in which a die comprising projections such as the rotating cylinder die of FIG. 6 is used to actually stamp the spacer film 130 to create cavities 170 as described above. The spacer film 130 and stamping aid 704 are both visible in FIG. 6, with the stamping aid 704 being wider than the spacer film 130. The stamped spacer film 130 and the stamping aid 704 are pulled into the first pair of film rollers 702c and compressed with a metalized film 706 that will serve as the substrate 160 and bottom electrode 150. The metalized film 706 may be a layer of polyimide, for example. When exiting the first pair of film rollers 702c, the stamping aid 704 is peeled from the spacer film 130 and metalized film 706 using a hard edge 708 to facilitate that separation.

The stamped spacer film 130 and metalized film 706 is pulled into the second pair of film rollers 702d and compressed with another metalized film 710 that will serve as the membrane 110 and top electrode 120 such that the spacer film 130 is sandwiched between the metalized films 706, 710. The metalized film 710 may be a relatively thin layer (e.g., anywhere from 3 μm up to and including 25 μm) of polyimide, for example. When the other metalized film 706, which is used for the substrate 160, is made from the same material, in at least some embodiments it is at least as thick, and up to twice as thick, as the metalized film 710 used for the membrane 110. This is to ensure the substrate 160 is at least as mechanically strong as the membrane 110. In embodiments in which the film 706 used for the substrate 160 is mechanically stronger than the film 710 used for the membrane 110, the film 706 used for the substrate 160 may be thinner than the film 710 for the membrane 110 while still resulting in the substrate 160 being at least as strong as the membrane 110.

The three films 706, 130, and 710 on exiting the second pair of film rollers 702d are fed into the pair of laminating rollers 702e and are laminated together into a finished film 712 of MEMS devices, such as that depicted in FIGS. 5B to 5D.

FIG. 7 depicts first and second pairs of film rollers 702c,d. In at least some other embodiments, those rollers 702c,d may be replaced with a single roller that receives and compresses both metalized films 706 and 710 against the stamped spacer film 130. Additionally or alternatively, when the two pairs of film rollers 702c,d are used, the thicker of the films 706, 710 may be fed through the second pair of film rollers 702d instead of the first pair of film rollers 702c as shown in FIG. 7.

### Applications to Products

Remote Control. Power consumption is a major challenge because many Internet-of-things (IoT) devices are battery powered and need to have a long lifetime in the field. A switched-off device reduces battery life but does not provide sensing when needed, so there is a need for an energy-efficient way to alert and turn on IoT devices. This means the devices need a wake-up receiver that can turn on/off the IoT devices. Ultrasound has several advantages for performing this task. It can use very short wavelength signals and therefore be much smaller than similar alarm receivers that use radio signals while operating at extremely low power and with a wider range (i.e., the ability to receive a signal from a larger angular distance). Such an ultrasound-based receiver listens for a low amplitude ultrasonic signal, which may be uniquely mapped to the device, indicating when the device should be turned on. In at least some embodiments, it may only require a nanowatt of signal power, which is a tiny draw on valuable battery energy reserves. Moreover, the range of such ultrasound signals is naturally restricted by virtue of being unable to propagate through acoustically opaque surfaces such as walls, so it can be limited to inside a room for example, which has valuable privacy advantages. This technique is extendible beyond simple wake-up signals and includes transmitting and receiving other information such as encoded passwords or other information. A further advantage is that the ultrasound frequencies do not interfere with the strictly controlled electromagnetic frequency ranges for IoT communications dictated by governmental regulatory bodies.

Poly-CMUT Sleeve. In at least some embodiments a poly-CMUT array may be fabricated on a stretchable substrate so that it behaves like an elastic fabric. This is useful when a tight fit is needed between the poly-CMUT and the target material, such as when the poly-CMUT comprises part of a sleeve that is sheathed on a pipe.

Structural integrity testing. In still other embodiments, transparent poly-CMUT arrays are used in non-destructive testing (NDT) of materials. Typically, x-ray imaging is used for inspection of materials, but the doses used contain a great percentage of ionizing radiation which in some cases produce internal damage to a test specimen. An x-ray transparent poly-CMUT array may additionally or alternatively instead be used to obtain an image, such as a hybrid image resulting from a combination of ultrasound and x-ray imaging, to potentially reduce the amount of x-ray energy needed.

Pipeline Monitoring. A CMUT array can be installed on a section of pipe at the time of placement of the pipe in the field in some embodiments. Alternatively, it can be installed on a section of pipe at the time of manufacture of the pipe to enable better integration with the pipe and protection of the poly-CMUT array from damage. At least some embodiments are useful for real time monitoring of pipelines underground in a form of NDT.

Hydraulics Testing. A poly-CMUT may be fabricated on a resilient substrate in some embodiments, so that it can deform with the deformation of a hydraulic hose during normal operation. Electrical interconnections and flexibility of substrate may be customized depending on the diameter and length of the piping to be wrapped.

Aircraft Wing NDT. In some embodiments, there is provided a rollable poly-CMUT array that may be installed around the perimeter of a wheel, which permits the array to be rolled quickly on to an aircraft wing. The poly-CMUTs in contact with the wing can then be used to perform ultrasound imaging. The poly-CMUTs may comprise part of a flexible fabric, for example,

If large-scale poly-CMUT transducer arrays need to be used to inspect plane wings or other aircraft for instance, a large film comprising a poly-CMUT array can be temporarily attached to a wing for inspection. A permanent monitoring solution may comprise, for example, incorporating the transducers inside the fuselage to protect the transducers from physical wear and environmental exposure.

Wearable poly-CMUT arrays. In another embodiment, a poly-CMUT array made according to the embodiments described herein is employed on human or animal tissue. The flexible or rigid array thus formed for medical or agricultural applications is useful for providing information on injuries on site when an accident has occurred. Emergency responders may, for example, wrap the injured person in the fabric and image the breaks and soft tissue injuries in the victim before initiating transport to medical care.

This practice may comprise checking legs, arms, ribs and spine for breaks, and checking for impact injuries in the skull.

Bandage for wounds. In at least some embodiments, a poly-CMUT array is fabricated into a bandage used to cover wounds during healing. For this purpose, a flexible substrate is used so that it can conform better to tissue. This poly-CMUT array bandage is also capable of monitoring tissue repair and delivering energy to the tissue under repair to increase the speed of the healing process. In another embodiment, the poly-CMUT array bandage is used to cavitate fluid in the tissue to support debridement.

Diagnostic Instrumentation. In other embodiments, a hybrid integration of transparent poly-CMUT arrays combines x-rays, ultrasound, photoacoustics, elastography, and/or a combination thereof, in a single system.

Chemical and Biological Sensing. A wearable poly-CMUT patch may be used for chemical and biological sensing by functionalizing the membrane of the poly-CMUT element. A functionalized membrane is sensitive to the presence of a chemical or biological substance that changes the mass loading of the membrane. For example, the resonant frequency of the poly-CMUT element depends on the material properties (e.g., mass, stiffness, and viscosity) of the membrane, analogous to a drum. In the presence of a particular chemical or biological substance intended to be “sensed”, the functionalized membrane may absorb some of the material and its physical properties are accordingly changed. The change in material properties can be detected, for example, by a change in the frequency, bandwidth, or amplitude of the resonant frequency. In particular, it is known that the change in resonant frequency is proportional to the relative change in the mass of the membrane.

Heart Monitor. A patch according to at least some embodiments acts as an emitter focusing the ultrasound pulses on skin towards the heart and a microphone recording the reflected waves. This patch acts as an airborne pulse-Doppler ultrasound system operating in the 20-60 kHz range. Example patch sizes range from 5 by 5 cm to 10 by 10 cm, for example.

Blood Pressure Monitor. In certain embodiments, a poly-CMUT wearable array uses ultrasonic Doppler flow measurements to determine blood pressure noninvasively in a patient population. Blood pressure may be measured using poly-CMUTs as described below and compared to an invasive arterial line or to the oscillometric Terumo Elemano™ blood pressure monitor. To measure blood pressure using poly-CMUTs, blood velocities in the radial artery are recorded by a fabric patch comprising a poly-CMUT array during cuff deflation. A sigmoid curve is fitted to a preprocessed velocity signal and the systolic and mean arterial pressures are determined. Applications include pre-eclampsia monitoring in pregnancy and ambulatory blood pressure monitoring in cardiac patients.

Transcranial focused ultrasound (FUS) combined with intravenously circulating microbubbles can transiently and selectively increase blood-brain barrier permeability to enable targeted drug delivery to the central nervous system. This approach may be used in patients with brain tumors, early Alzheimer's disease, and amyotrophic lateral sclerosis. A challenge addressed by at least some embodiments is that for widespread clinical adoption of FUS-mediated blood-brain barrier permeabilization to occur is the development of systems and methods for real-time treatment monitoring and control, to ensure that safe and effective acoustic exposure levels are maintained throughout the procedures.

Transmitter and receiver electronics, sometimes called transceivers, that may be incorporated into the above applications are commercially available from Verasonics™, US4US™, Interson™, and Texas Instruments™, for example.

At least some embodiments will be more readily understood by referring to the following examples which are given to illustrate various embodiments.

### Example 1

Working poly-CMUTs were created in a fully mechanical process. First, polyamide was metalized to create the needed electrodes. A thin (900 nm thick) Mylar™ film was vertically stamped using a 0.5 mm leather stamp; this film acts as the spacer film 130 of FIG. 1. Leather stamping dies were used to create the shaped cavities in the prototype. More generally, the Mylar film may be any generic biaxially oriented polyethylene terephthalate film having a thickness ranging from 600 nm to 1.5 μm.

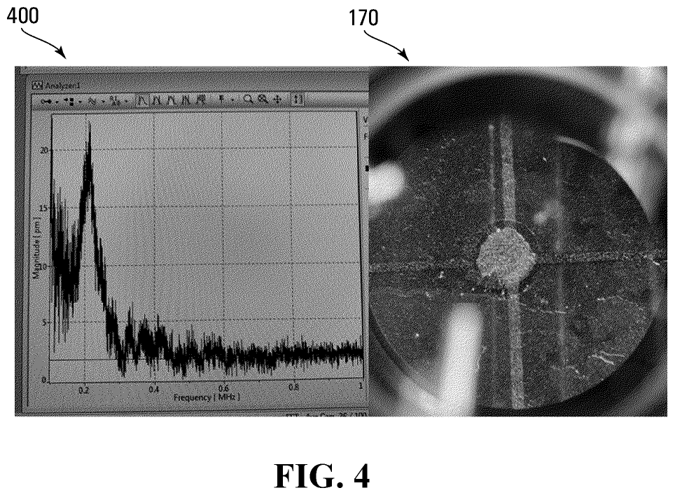

FIG. 3 shows the stamped 900 nm Mylar film 130 to show the feasibility of mechanically stamping such a thin film. After stamping and set up for use, this mask is used as a template for stamping and metal evaporation.

The stamped film was then aligned to the metalized polyamide film and laminated together at a temperature of 235° C. combined with pressure in a roll laminator. The resulting layup and a four cavity device 300 are shown in FIG. 2B.

The exact layup of the created prototype 200, with the spacer film 130 being PET in the form of Mylar™, is illustrated in FIG. 2A. In this embodiment, the prototype 200 lacks the insulation layer 140 of FIG. 1. However, it includes the cavity 170, which is formed by stamping the spacer film 130; a membrane 110 made of Kapton™ that is metalized and whose metalized portion forms the top electrode 120; and a substrate 160 made of Kapton™ that is metalized and whose metalized portion forms the bottom electrode 150.

The layers may then be connected to a bias tee with 120 V DC and 60 V AC and scanned with a LDV to find the resonant frequency and thereby confirm the success of fabrication.

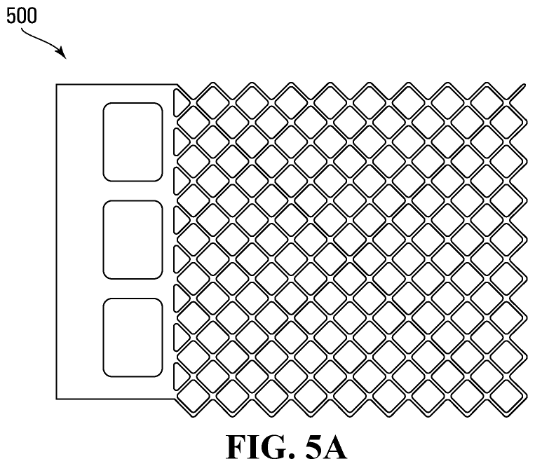

In the right-hand side of FIG. 4, a single cavity 170 manufactured according to an embodiment is shown under a 10× microscope. Both electrodes and the larger outline of the cavity 170 are visible, and the resulting LDV scan 400 to the left reveals a resonant frequency of roughly 230 kHz. The magnitude of displacement of the membrane under 120 V DC and 60 V AC with varying frequencies show the resonant frequency at ˜230 kHz and evidence the fabrication of a working prototype. The measurement was done in a LDV.

### Example 2

This example is directed at a novel MEMS fabrication method using a poly-CMUT as an example MEMS device. In order to use this entirely mechanical fabrication method, three main components are used. The first two components are two films of the same or varying thickness that can either be one homogenous material or a laminate of several materials are obtained; these films are used for the membrane 110 and substrate 160. To build a poly-CMUT those films are first metalized to for the electrodes 120 and 150. For the described prototypes in which the films respectively comprise 25 μm and 100 μm thick Kapton™, the films are metalized with 100 nm gold. The metallization can either be conformal or patterned depending on the architecture of the device. The third component is a very thin spacer film 130, acting as spacer film. In this example of a poly-CMUT, this spacer film 130 was a thin layer (900 nm) of Mylar™. This spacer film 130 is then stamped to create the shaped cavities needed to permit the movement of the poly-CMUT membranes. The resulting films are laminated together. In the case of the poly-CMUT, a laminator with rolls heated to 230° and a pressure of 1 bar resulted in permanent lamination. The parameters of this process vary depending on the materials used and the desired characteristics of the resulting device. In one example, the metalized substrate and membrane are insulated by adding a very thin layer of acrylate or SiO₂ or similar insulators. This can be done with either one or both of the two metalized films used for the electrodes.

In this disclosure, the word “comprising” is used in a non-limiting sense to mean that items following the word are included, but items not specifically mentioned are not excluded. It will be understood that in embodiments which comprise or may comprise a specified feature or variable or parameter, alternative embodiments may consist, or consist essentially of such features, or variables or parameters. A reference to an element by the indefinite article “a” does not exclude the possibility that more than one of the elements is present, unless the context clearly requires that there be one and only one of the elements.

In this disclosure the recitation of numerical ranges by endpoints includes all numbers subsumed within that range including all whole numbers, all integers and all fractional intermediates (e.g., 1 to 5 includes 1, 1.5, 2, 2.75, 3, 3.80, 4, and 5 etc.). In this disclosure the singular forms “an”, and “the” include plural referents unless the content clearly dictates otherwise. Thus, for example, reference to a composition containing “a compound” includes a mixture of two or more compounds.

In this disclosure term “or” is generally employed in its sense including “and/or” unless the content clearly dictates otherwise.

It is contemplated that any part of any aspect or embodiment discussed in this specification can be implemented or combined with any part of any other aspect or embodiment discussed in this specification, so long as such implementation or combination is not performed using mutually exclusive parts.

While example embodiments have been described above and illustrated in the accompanying drawings, it will be evident to those skilled in the art that modifications may be made without departing from this disclosure. Such modifications are considered as possible variants comprised in the scope of the disclosure.

1. A method of fabricating an array of micro-electrical mechanical systems devices, the method comprising:
(a) obtaining a sheet of material from which to form cavities for the devices;
(b) projecting physical or energy projections into the material to form the cavities in the material;
(c) respectively contacting upper and lower surfaces of the material with the cavities with upper and lower metalized films; and
(d) respectively bonding the upper and lower surfaces of the material with the upper and lower metalized films.

2. The method of claim 1, wherein the physical projections are projected into the material to form the cavities.

3. The method of claim 2, wherein the physical projections comprise a punching stamp.

4. The method of claim 2, wherein the physical projections comprise a stamp die.

5. The method of claim 2, wherein the physical projections comprise a rotating cylinder die.

6. The method of claim 1, wherein the energy projections are projected into the material to form the cavities.

7. The method of claim 6, wherein the energy projections comprise lasers.

8. The method of claim 6, wherein the energy projections comprise electrical discharges.

9. The method of claim 6, wherein the physical projections comprise steam jets.

10. The method of claim 1, wherein the material is polymeric.

11. The method of claim 10, wherein the material comprises polyimide.

12. The method of claim 1, wherein the material comprises polyethylene terephthalate.

13. The method of claim 12, wherein the material is biaxially oriented polyethylene terephthalate and is between 600 nm to 1.5 μm thick.

14. The method of claim 1, wherein the material is metallic.

15. The method of claim 1, wherein the MEMS devices are capacitive micromachined ultrasonic transducers.

16. The method of claim 14, wherein the MEMS devices are polymeric capacitive micromachined ultrasonic transducers.

17. The method of any one of claims 1-to 16, wherein the upper and lower surfaces of the material with the cavities are contacted with the upper and lower metalized films such that metalized portions of the upper and lower metalized films are respectively situated in the cavities.

18. The method of claim 1, wherein the bonding comprises laminating.

19. The method of claim 18, wherein the laminating is performed using a roll laminator at a temperature between 210° C. and 260° C.

20. The method of claim 19, wherein the laminating is performed at a pressure between 1 bar and 5 bar.

21. The method of claim 1, wherein the bonding comprises gluing.

22. The method of claim 1, wherein the lower metalized film comprises a flexible substrate of the devices.

23. The method of claim 1, wherein the metalized films respectively comprise lattice patterns, and wherein the cavities are located at locations at which the lattice patterns overlap.

24. An apparatus for fabricating an array of micro-electrical mechanical systems devices, the apparatus comprising:
(a) a pair of stamping rollers, wherein the pair of stamping rollers comprises a cylinder die and is configured to receive and stamp cavities into spacer film using the cylinder die;
(b) at least one pair of film rollers, wherein the at least one pair of film rollers is configured to receive the stamped spacer film and metalized films and to compress the stamped spacer film between the metalized films; and
(c) a pair of laminating rollers configured to receive and laminate the compressed spacer and metalized films.

25. The apparatus of claim 24, wherein the at least one pair of film rollers comprises a first pair of film rollers and a second pair of film rollers, wherein:
(a) the first pair of film rollers is configured to receive and compress the stamped spacer film and a first one of the metalized films; and
(b) the second pair of film rollers is configured to receive the spacer film and the first one of the metalized films after passing through the first pair of film rollers and a second one of the metalized films, and to compress the stamped spacer film between the metalized films,
wherein the first one of the metalized films is thicker than the second one of the metalized films.

26. The apparatus of claim 25, further comprising:
(a) a stamping aid roller pair configured to receive and compress the spacer film and a stamping aid, wherein the compressed spacer film and stamping aid are fed into the pair of stamping rollers and into the first pair of film rollers; and
(b) a hard edge positioned to peel the stamping aid away from spacer film after exiting the first pair of film rollers.
